(19) United States
(12) Patent Application Publication
(10) Pub. No.: US 2010/0289044 A1
(43) Pub. Date: Nov. 18, 2010

(54) WAVELENGTH CONVERSION FOR PRODUCING WHITE LIGHT FROM HIGH POWER BLUE LED

(75) Inventors: Michael R. KRAMES, Los Altos, CA (US); Gerd O. MUELLER, San Jose, CA (US); Regina B. MUELLER-MACH, San Jose, CA (US); Hans-Helmut BECHTEL, Aachen (DE); Peter J. SCHMIDT, Aachen (DE)

Correspondence Address: PHILIPS INTELLECTUAL PROPERTY & STANDARDS, P.O. BOX 3001, BRIARCLIFF MANOR, NY, 10510, US

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/464,327

(22) Filed: May 12, 2009

(51) Int. Cl. H01L 33/00

(52) U.S. Cl. 257/98; 257/E33.067; 257/E33.061

(57) ABSTRACT

A white light LED is described that uses an LED die that emits visible blue light in a wavelength range of about 450-470 nm. A red phosphor or quantum dot material converts some of the blue light to a visible red light having a peak wavelength between about 605-625 nm with a full-width-half-maximum (FWHM) less than 80 nm. A green phosphor or quantum dot material converts some of the blue light to a green light having a FWHM greater than 40 nm, wherein the combination of the blue light, red light, and green light produces a white light providing a color rendering of R_{a,8}>90 and a color temperature of between 2500K-5000K. Preferably, the red and green converting material do not saturate with an LED die output of 100 W/cm² and can reliably operate with an LED die junction temperature over 100 degrees C.

### FIELD OF THE INVENTION

The present invention relates to wavelength conversion materials for producing white light from a high power blue light emitting diode (LED).

### DESCRIPTION OF RELATED ART

A bare light emitting diode (LED) die typically emits light within a narrow wavelength (e.g., 25 nm at half-maximum), where the peak wavelength is primarily determined by the materials forming the active layer. For example, GaN, InGaN, and AlInGaN materials are used to produce blue to green light. An AlGaInP material is used to produce yellow-green to red light.

To create a white light LED, a blue LED die is typically covered with either a yellow-green phosphor, such as a YAG phosphor, or a combination of red and green phosphors so that the combination of the light generated by the phosphor and the blue light leaking through creates white light.

A light source's color rendering index (CRI) describes a light source's ability to accurately render the colors of the objects it illuminates. The CIE color rendering index (CRI) originates from the Commission Internationale de l'Eclairage, Method of Measuring and Specifying Colour Rendering Properties of Light Sources, CIE 13.3 (1995), and is a metric for assessing the color rendering performance of light. The color rendering by a fluorescent light bulb is about 80 due to its low amount of light intensity in the red visible range. A fluorescent bulb is commonly said to output cool white light due to the relatively large amount of blue light in its spectrum. The combination of a blue LED and YAG phosphor also has poor color rendering due to its low level red light emission.

In the following description, the so-called General Color Rendering Index, Ra, will be used. However, some special indices, such as R9, which measures the rendering of a deep red object, have importance for user acceptance. The majority of fluorescent lights have either negative or very small R9 values and, in general, there seems to be a correlation of R9 with spectral lumen equivalent in common light sources.

A color rendering of 90 and above, such as produced by an incandescent light, is considered to be the most pleasing to the human eye, and white light LED light sources that achieve CRI>90 are most likely to be the type that consumers will buy to replace incandescent bulbs in the home. An incandescent bulb produces a pleasing warm white light with a color temperature of 2800-3300K, and the emission spectrum is close to that of a Planckian radiator at the same temperature. A color temperature of between 2700-3000K is considered the most pleasing for living spaces since it is the most flattering for skin tones and clothing. Cool light is considered to be 3600-5500K, typical for an office that uses fluorescent bulbs.

An important consideration in white light LEDs is the luminous efficacy in lumens per Watt, which takes into account the human eye sensitivity for visible light in the wavelength range of 380 to 780 nm. The luminous efficacy of an incandescent bulb is very small, because much of the power is used to produce infrared light (>700 nm, where the human eye sensitivity is low) and is wasted as heat.

A medium power blue LED in combination with red and green wavelength conversion materials can be tailored to produce light with CRI>90. However, the phosphor materials used today for producing white light LEDs are inadequate to efficiently perform the required wavelength conversion for state-of-the-art, high power and hot blue LEDs. A high power blue LED outputs at least 100 W/cm² of radiant flux. For a 1 mm² chip, that is an output of 1 W. The human eye is about ten times as sensitive to green light as it is to deep blue and red light. One Watt of green light at 555 nm produces 683 lumens (a 40 W light bulb outputs 600 lumens). For blue LED light with a peak emission at about 475 nm, 1 W equates to about 100 lumens. Such a high power may produce an active layer junction temperature of 100° C. or more. A modern white light high power LED has a spectral lumen equivalent of less than 340 lm/W (white lumens divided by white Watts) and a luminous efficacy of <150 lm/W (white lumens divided by electrical Watts).

In order to maximize both the color rendering and the luminous efficacy of a white light LED, the red phosphor must have a narrow full-width-half-maximum (FWHM) wavelength to prevent any appreciable light power being wasted due to producing light outside of the human eye sensitivity above 700 nm. A typical red phosphor used today (e.g., CaAlSiN₃:Eu) has a FWHM of about 90 nm. Certain types of red phosphors, such as Y₂O₂S:Eu³⁺, Bi³⁺, and YVO₄:Eu³⁺, Bi³⁺, have an emission peak of 620 nm and a FWHM of about 2 nm but such phosphors are too slow to decay and would become saturated under very bright blue light (e.g., above 100 W/cm²) produced by a high power blue LED. Sulfide based red phosphors such as SrS:Eu would also not be useful with high power blue LEDs since the phosphors tend to degrade with the heat produced by such a blue LED or under the environmental conditions (e.g., humidity) required in solid state lighting applications.

If the phosphor is spaced away from the blue LED, then high blue light intensity and heat would not be a significant factor. However, even when an Eu3+ doped phosphor is remotely energized by a blue LED, such phosphors are still not very desirable for creating white light. Eu3+ produces in many host materials narrow emission lines around 611-615 nm, which fluorescent lights rely on. However, they lead to negative or very small R9 values. Moreover, the absorption of Eu3+ phosphors in the range >395 nm is so small that impractically large amounts of such materials would have to be placed into the blue pump light path. Very strong back scattering would lead to low package efficiency even in remote phosphor applications. In proximity applications of such materials, such as when the phosphor material is deposited directly over the blue LED die, the saturation of those slow transitions would exclude Eu³⁺ doped materials completely.

Presently, no highly efficient, high power white light LEDs are publicly known with a CRI>90 that combines a blue LED with red and green down-converters.

Quantum dots have been used for wavelength conversion. Quantum dots, or semiconductor nanoparticles, are the only known color converters for which the width (FWHM) of the emission band can be controlled without strongly influencing the peak wavelength of emission. The FWHM output from quantum dots is controllable by adjusting the particle size distribution of the quantum dots. In phosphors, there is a fixed interrelation between FWHM and peak wavelength.

What is needed is a combination of green and red wavelength conversion materials that can be excited by a high power blue LED, that results in a warm white light (2700K-3000K), that results in a color rendering of 90+, that results in a very high spectral lumen equivalent (>300 lm/W), and that results in a high luminous efficacy white light source (>150 lm/W). For wavelength conversion materials that will be deposited over the LED, such materials need to not saturate with a blue light LED output of >100 W/cm² and must withstand high LED junction temperatures (e.g., >100° C.).

### SUMMARY

The next generation of white light LEDs is addressed herein. Energy efficiency has become more and more a criteria for purchasing consumer products. Replacing inefficient incandescent bulb lamps with bright, energy efficient white light LED lamps is a very important component of reducing energy consumption in the home.

An extensive analysis is provided herein to illustrate how Applicants have determined the most desirable properties of red and green wavelength conversion materials to use in conjunction with high power blue LEDs to efficiently create white light comparable to that produced by an incandescent bulb. Finally, various and novel material/LED combinations are identified for creating a white light LED with the necessary properties to replace conventional bulbs.

In one embodiment, the green wavelength conversion material is a phosphor and the red wavelength conversion material is a quantum dot material. In another embodiment, both wavelength conversion materials are phosphors. In another embodiment, both red and green wavelength conversion materials are quantum dot materials.

A high power blue LED (>100 W/cm²) is used as the pump source. The LED die emits a narrow FWHM bandwidth (e.g., 25 nm) with a peak wavelength of between 430-480 nm.

In one embodiment, a red wavelength conversion material is deposited over the blue die, either directly or over an intermediate layer. Alternatively, the red wavelength conversion material may be in the form of a prefabricated plate affixed to the top of the blue die. Alternatively, the red wavelength conversion material is remote from the LED die and within the light path of blue light in an extended lighting system. The red wavelength conversion material has a peak red light emission between 590-625 nm, depending on the color rendering requirements. The red wavelength conversion material has a FWHM emission of <50 nm so that only an insignificant portion of the red light produced is outside of the visible range. A resulting white light LED using the red wavelength conversion material creates a CRI>90 and produces a warm white light (2700K-3000K).

If the red wavelength conversion material is to be in contact with the LED die, it must not saturate with a pump light at 100 W/cm² in order to achieve high efficiency, and it must also remain reliable at over 100° C. Other intensities and temperatures that may be achieved by blue LED dies may be up to 150 W/cm² and 125° C., and the down-conversion materials would ideally operate adequately at those characteristics without saturation or breaking down.

Applicants have identified suitable red wavelength conversion materials. CdSe and InP based quantum dots are the most suitable red converters. Suitable red phosphors are also identified and include various types of Eu(II) doped nitride phosphors. Values of FWHMs down to 30 nm for the red down-converter material have been demonstrated and could be further reduced if necessary.

The preferred FWHM (less than 80 nm) red phosphor has a relatively low quenching temperature so spacing the phosphor from the LED die surface in an optical path may be preferred over coating the die with the phosphor.

The light from the blue LED die combines with the disclosed red conversion materials and green conversion materials to produce white light having the characteristics described above.

A suitable green phosphor can have a much higher FWHM because the entire bandwidth of green is visible to the human eye. Generally, to achieve a high spectral lumen equivalent of >300 lm/W, a correlated color temperature (CCT) of 2700K, and a CRI of >90, the FWHM of the green phosphor needs to be greater than about 60 nm and the FWHM of the red phosphor needs to be less than 50 nm. This assumes that the pump is a blue LED emitting a peak wavelength between 430-480 nm. Suitable green phosphors may be members of the Ce(III) activated garnet family.

Suitable green emitting quantum dots are based preferentially on CdS but have to have smaller particle sizes than red emitting ones. Sizes around 2.5 nm will give peak wavelengths around 530 nm. A relatively broad particle size distribution (PSD) from 2 to 2.6 nm can yield a reasonably wide emission, such as including 50 nm FWHM. As for the desired high Ra, the green emission should not be too narrow. Producing larger than 50 nm FWHM quantum dot emissions has not yet been a goal.

### BRIEF DESCRIPTION OF THE DRAWINGS

FIG. 1 illustrates a blue AlInGaN LED die, mounted on a submount, having one or more wavelength conversion layers either affixed to its top surface or deposited over its top surface.

FIG. 2 illustrates the blue LED die of FIG. 1 with the wavelength conversion materials separated from the LED to reduce the effective heat and light intensity on the materials.

FIGS. 3A-3F illustrate the various luminous efficiencies (lumens per electrical Watt) achieved using a blue pump LED with 75% power conversion efficiency (peak wavelength identified in each figure) with green and red wavelength conversion materials having various FWHM bandwidths.

FIG. 4 compares the lumen equivalents of three white light LED spectra (simulated).

FIG. 5 depicts the maximum white luminous efficacy (lumens per electrical Watt, assuming a blue LED of 75% power conversion efficiency) for three color temperatures, using a red down-converter with a FWHM of 75 nm and 25 nm.

FIGS. 6A and 6B are graphs illustrating the maximum practical 2700K white luminous efficacy and color rendering properties as a function of red down-converter FWHM, using a particular green down-converter FWHM and blue LED pump (460 nm, 75% efficiency).

FIG. 7 illustrates the relationship between Stokes shift and FWHM of emission for Eu² emitters.

FIG. 8 illustrates the phonon frequency and S values that result in red emission with a peak at 615 nm and FWHM 50 nm at T=100° C.

FIGS. 9A and 9B show suitable coordination polyhedra for activator sites in red emitting nitride phosphor systems.

FIG. 10 illustrates the emission spectrum (446 nm excitation) of Ba₂Ca₂Si₆ON₁₀:Eu(1%), showing red peak emission at 622 nm and FWHM=50 nm.

FIG. 11 illustrates peak maxima, CIE×color coordinates and lumen equivalent values that can be obtained with different BCSSNE ceramics.

### DETAILED DESCRIPTION

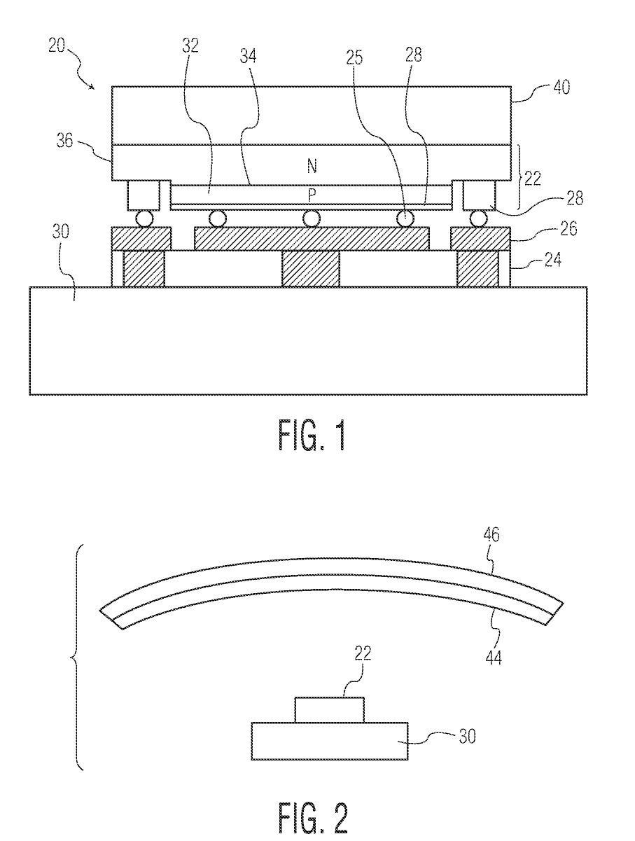

FIG. 1 is a cross-sectional view of a white light LED 20 formed in accordance with one embodiment of the invention. A high power (>100 W/cm²) blue light LED die 22 is soldered or ultrasonically welded to a submount 24 using gold bumps 25 or any other means. The submount 24 has metal contact pads 26 on its surface to which the bottom electrodes 28 on the LED die are electrically connected. The LED die is a flip-chip. The contact pads 26 lead to other conductors formed on the periphery or underside of the submount 24 for connection to a printed circuit board 30, which is in turn connected to a power supply such as a current source. The LED die 22 may be formed using AlInGaN materials and preferably emits blue light that has a peak wavelength of about 430-480 nm. The die 22 comprises a bottom p-layer 32, an active layer 34, and a top n-layer 36. Each layer may include a plurality of layers. In other embodiments, the location of n and p layers may be reversed, and the device may be a non-flip-chip. The top surface of the blue LED die may be any size, with typical sizes being about 1 mm².

Affixed to the top surface of the LED die 22 is a phosphor plate 40 containing a red down-converter material and a green down-converter material. Alternatively, there is a separate red plate below a green plate. The size of each plate may approximately match the size of the LED die 22. Some blue light leaks through the phosphor, so the resulting light is white. In one embodiment, the plates are smaller than the LED die 22 (e.g., up to 50% smaller) to create a larger blue component in the white light or to allow green and red phosphor plates to be placed side by side. With a thin LED die 22, there will be insignificant side emission.

In one embodiment, the thickness of each plate or the combined plate is between 50-300 microns, depending on the type of phosphor used, the type of blue LED used (e.g., higher power LEDs may need thicker plates), the density of the phosphor, and other factors which would be understood by those in the art.

The platelet may be sintered phosphor powder or phosphor powder disbursed in a transparent binder, such as silicone. Or, it may comprise semiconductor nano-particles (quantum dots) embedded into a suitable matrix such as epoxy or silicone. Or, it may be a hybrid (e.g., phosphor in a binder where the binder contains semiconductor nanoparticles).

If overlapping red and green plates are used, placing the red plate beneath the green plate is advantageous because the red down-converter generally absorbs the green photons, while the green down-converter does not significantly affect the red photons. This tends to result in improved down-conversion efficiency.

The down-converter layer over the LED die 22 may instead be a film deposited over the LED die instead of preformed plates.

FIG. 2 illustrates another embodiment of a white light source where the blue LED die 22 is separated from a curved red down-converter sheet 44 and a green down-converter sheet 46. The separation from the die 22 may be from a few millimeters to greater than 1 centimeter. Either one or both down-converting materials may be separated from the die. In the former case, one down-converter is still proximal to the LED die as shown in FIG. 1. Separating the phosphors from the LED die ameliorates photo-saturation of the phosphors and excessive heating of the phosphors. The sheets 44/46 may be supported by a clear silicone lens over the LED die 22. As in FIG. 1, the down-conversion media may be phosphors, or semiconductor nanoparticles (quantum dots), or a combination of phosphor and quantum dots. The two sheets 44/46 may be formed as a single sheet of mixed red and green converter materials, if practical.

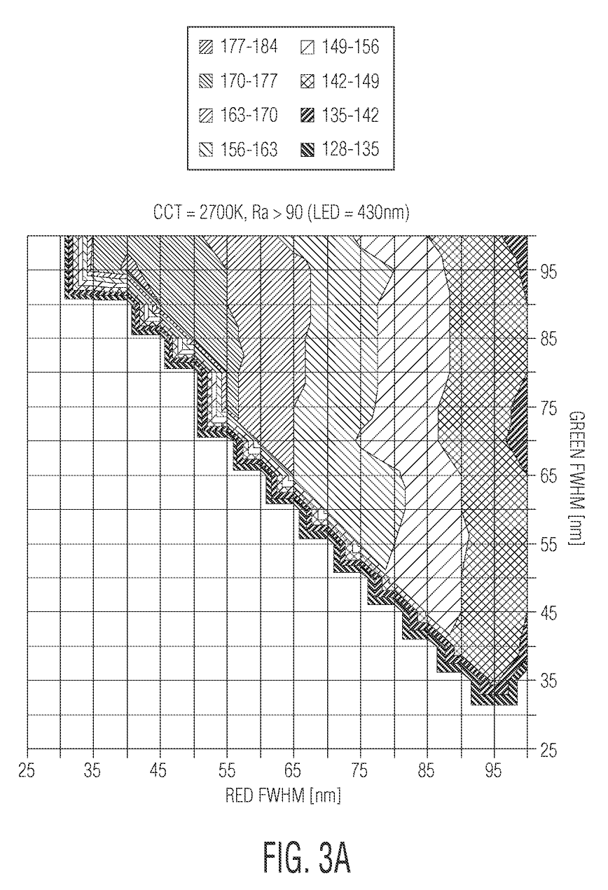

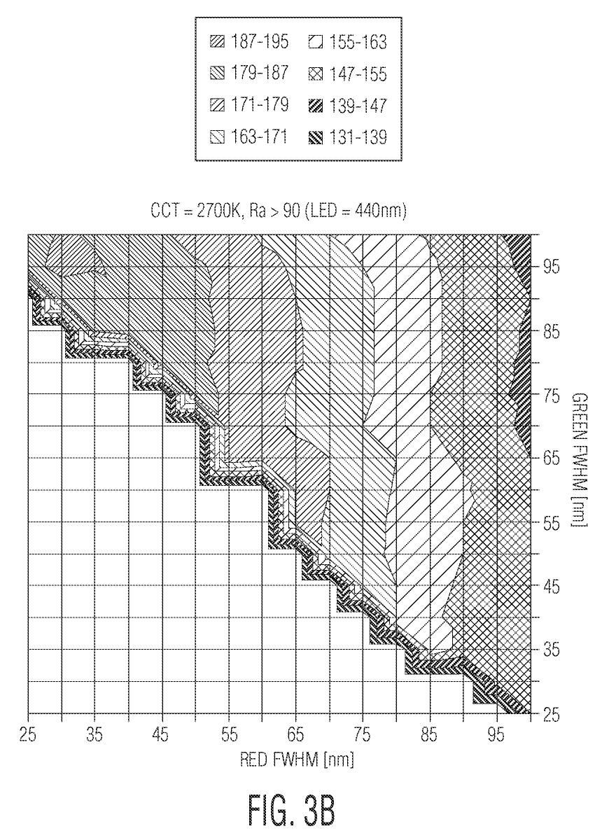

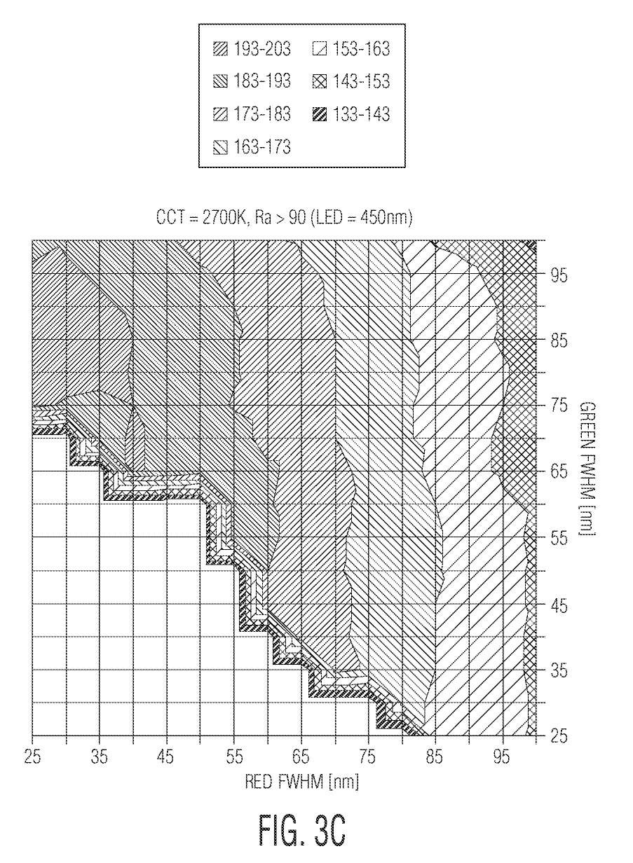

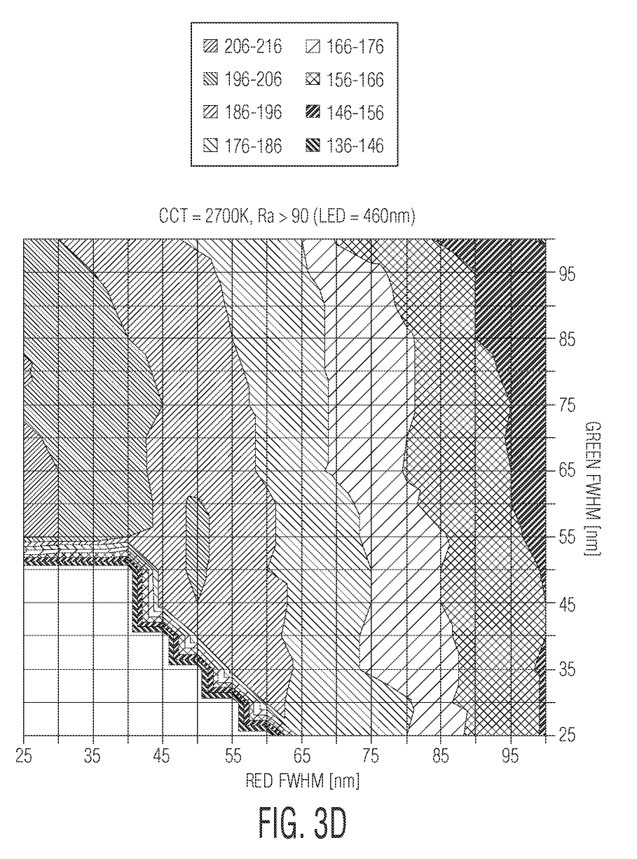

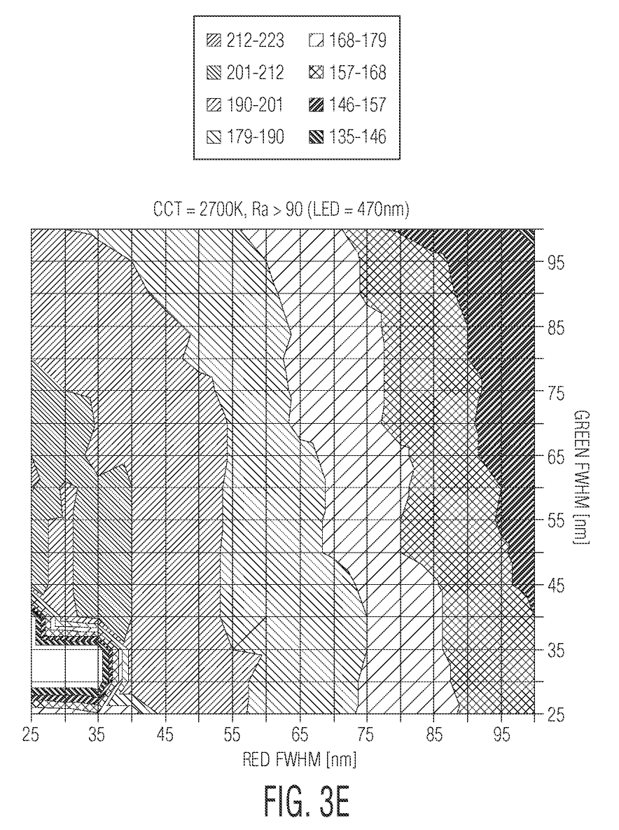

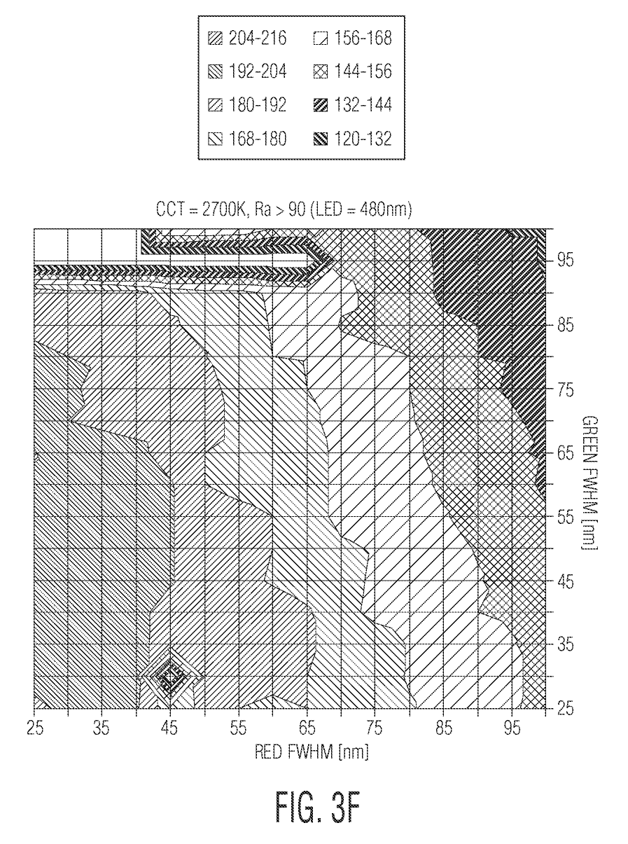

We have performed computer simulations of combining different blue LED dies with red and green wavelength conversion materials having different FWHMs. The plots of FIGS. 3A-3F show the achievable luminous efficacy (lumens per electrical Watt) from 120 lm/W through 223 lm/W, for blue-pumped emission wavelengths of 430 to 480 nm in steps of 10 nm using down-conversion to generate white light. The power conversion efficiency of the pump LED is assumed to be 75%. Quantum efficiencies of the green and red down-converting materials are assumed to be 100%, and an optical loss of 10% associated with down-conversion is assumed. The calculations are for a target spectrum of 2700K wherein a minimum color rendering of R_{a,8}˜90 is maintained. R_{a,8} is a known standard when establishing a color rendering index (CRI). There are 14 color samples that are measured against for rendering, but only the first 8 are used in practice, with the CRI taken as the average of rendering indices for those 8 color samples. For each data point, the green and red peak emission wavelengths have been optimized.

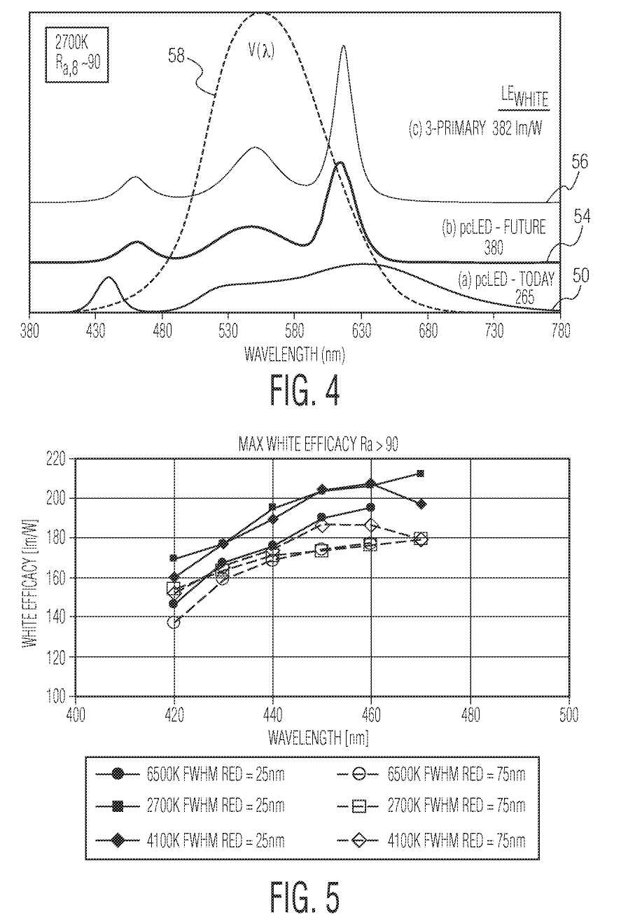

From the plots, we see that the gradient in efficiency is substantially along the horizontal axis, which corresponds to the red down-converter FWHM. This is because of the eye sensitivity roll-off in the red wavelength regime. Broad red emitters generate much of their light in the deep red, even near infra-red, and thus generate very low lumens. Today's Luxeon° warm white LEDs employ a red phosphor (CaAlSiN₃:Eu) with a FWHM of 95 nm. The lumen equivalent of the white spectrum is only ˜265 lm/W. This compares to ˜380 lm/W for an optimized spectrum (see FIG. 4).

In FIG. 4, three white light LED spectra (simulated) are compared, where each LED has an output emission CCT of ˜2700K. The curves are vertically offset only for ease of distinguishing one curve from another. The bottom curve 50 uses a YAG+CaAlSiN₃:Eu phosphor with a blue pump wavelength of ˜440 nm, (R_{a,8}=88), which is used in today's Luxeon° warm white LEDs, to achieve a spectral lumen equivalent (LE) of ˜265 lm/W. The middle curve 54 utilizes a 25 nm FWHM red conversion material with a blue pump wavelength of ˜460 nm (R_{a,8}=90), to achieve LE ˜380 lm/W. A green phosphor with a 75 nm FWHM is assumed to be used in the middle curve 54. The top curve 56 uses three primary red-green-blue (RGB) LEDs (R_{a,8}=90) to create an optimized spectrum, to achieve ˜382 lm/W. The human eye responsivity, V(λ), is given by the curve 58. (Note that the graphs of FIGS. 3A-3F divide up the ranges into luminous efficacy (lumens per electrical Watt) rather than the spectral lumen equivalent (lumens per optical Watt) used in FIG. 4.)

FIG. 5 depicts the maximum white efficacy (lm/W) for three color temperatures, where the color rendering is maintained to R_{a,8}>90, as a function of the blue LED die peak emission wavelength. The plot contains graphs for an ideally small FWHM of 25 nm for the red down-converter and a FWHM of 75 nm for the red down-converter. An FWHM of 75 nm is currently achieved with a BSSNE red phosphor platelet. For 6500 K, R_{a,8}>90 cannot be realized with a 470 nm pump LED. White efficacy increases with decreasing FWHM of the red phosphor, most pronounced for low correlated color temperature (CCT). White efficacy decreases with decreasing pump LED emission wavelength below ˜450 nm, suggesting that 450-470 nm is the desired pump LED wavelength for the highest-performing white down-converted LEDs. Such blue LEDs are manufactured by the present assignee.

The low spectral lumen equivalent (LE) for today's warm white LEDs has everything to do with the broad FWHM of the available red phosphors. CaAlSiN₃:Eu, for example, which is used in Luxeon® warm white, has a FWHM of 95 nm. The effect of a reduced FWHM of the red emitter in white LEDs on total white luminous efficacy is dramatic. There are two reasons: (1) reducing FWHM allows more power to overlap the human eye sensitivity regime, increasing spectral luminous efficacy, and (2), narrower red emission means less red power is necessary to generate the required white point. The latter is important because red emission is inherently the least efficient to generate for down-conversion LEDs due to Stokes loss. Stokes loss is due to the emitted energy of a photon having less energy than the absorbed photon.

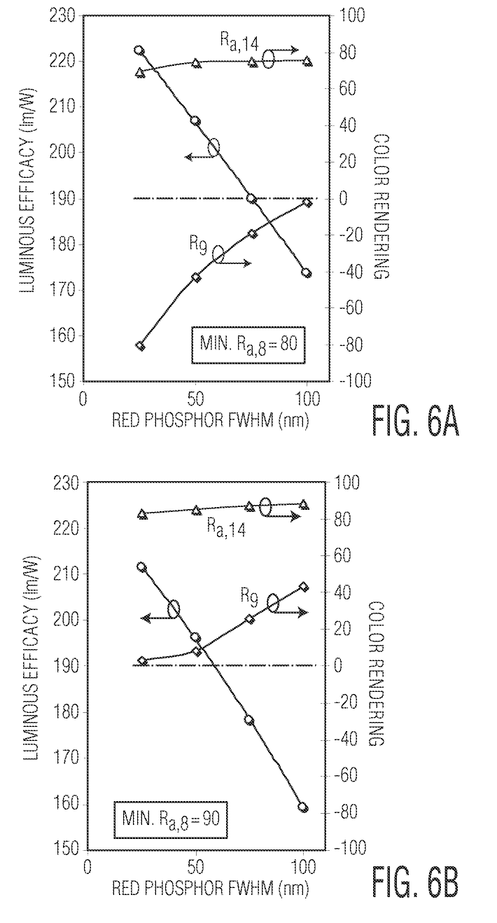

The combined effect is severe and is illustrated in FIGS. 6A and 6B, where maximum achievable white LED luminous efficacy is plotted vs. red down-converter FWHM for both R_{a,8} ˜80 (FIG. 6A) and R_{a,8} ˜90 (FIG. 6B). FIGS. 6A and 6B illustrate the maximum practical 2700K white down-conversion LED luminous efficacy (lumens per electrical Watt), and color rendering properties R_{a,14} and R₉, as a function of red down-converter FWHM. Both sets of calculations assume a 75 nm FWHM green phosphor, a 460 nm pump LED with efficiency=75%, and a 10% color mixing loss.

It is important to note that maximum practical efficacies are achieved for down-converters with FWHM approaching 25 nm. The narrowest publicly known Eu²⁺ emission is ˜33 nm for a cyan phosphor (BaSi₂O₂N₂:Eu) pumped by blue. This is for a ˜50 nm Stokes shift which is substantially smaller than that available for blue-pumped red (>140 nm). The importance of narrow red emitter FWHM makes other down-conversion materials, such as semiconductor nano-particles, which can in principle obtain very low FWHMs, interesting alternatives to conventional phosphors.

### Down-Converting Materials

Red Phosphors

In combination with a broad green emitting phosphor, an optimized red emitting phosphor should peak at 605-625 nm, depending on color rendering requirements. A material system that has efficient luminescence in this spectral range (in combination with very good thermal quenching properties) is (Ba,Sr)₂Si₅N₈:Eu (BSSNE) with a Ba/Sr ratio in the 3-1 range. This ceramic material (and others) can be provided in powder or a pressed-plate (Lumiramic™) form. Lumiramic™ is a Philips Lumileds trademark used herein to describe a thin phosphor platelet affixed over an LED die. The emission band position can be tuned from 590-615 nm (FWHM=72-76 nm) while maintaining good photothermal stability. A platelet has been shown to be more reliable than phosphor powder suspended in a binder under the high heat produced by a high power blue LED die. High quantum efficiency (ηₚₕ>90%) has been demonstrated for red-shifted BSSNE ceramics.

As shown above, for >200 lm/W white down-conversion LEDs, red is the most critical spectral component since the spectral position and width of the red emission directly determines luminous efficacy and color rendition. Besides high efficiency and stability, a suitable Eu²⁺ doped host lattice for narrow emission red should fulfill at least part of the following requirements:
1. Strong, covalent activator—ligand interactions are needed to efficiently lower the net positive charge of the activator. A medium condensed nitride lattice with coordinating N^{[2]} ligands is considered as most suitable.
2. The host should contain only one substitutional lattice site for the activator ion and no statistical site occupation within the host structure (as found for SiAlONes or CaSiAlN₃:Eu) to avoid inhomogeneous broadening of the emission band. In case that more than one substitutional lattice is present in the host lattice, the substitutional lattice sites should differ significantly in chemical nature to avoid spectral overlap of emission bands.
3. The activator site should show a high symmetry to limit possible structural relaxation modes of the activator in the excited state. Preferably, the activator site is larger (Ba site) than Eu²⁺ to hinder excited state relaxation and thus minimize the Stokes shift.

Such systems include: Ba(Sr)—Si—Al—N(O):Eu, Ba(Sr)—Si—Mg—N(O):Eu, Ba(Sr)—Si—B—N:Eu, Ba(Sr)—Ga—N:Eu, Ba(Sr)—Ga—Mg—N:Eu, or Ba(Sr)—Ca—Si—N(O):Eu.

A red phosphor with a peak emission of 615 nm is ideal. From measured spectra of alkaline earth sulfides (CaS:Eu, 654 nm peak, 63 nm FWHM; MgS:Eu, 591 nm peak, 39 nm FWHM), it can be derived that FWHM ˜50 nm (F=1324 cm⁻¹ at 615 nm peak) is feasible for Eu(II) in ideal octahedral coordination, even in a strongly ionic environment as found for the sulfides with its limited host lattice rigidity.

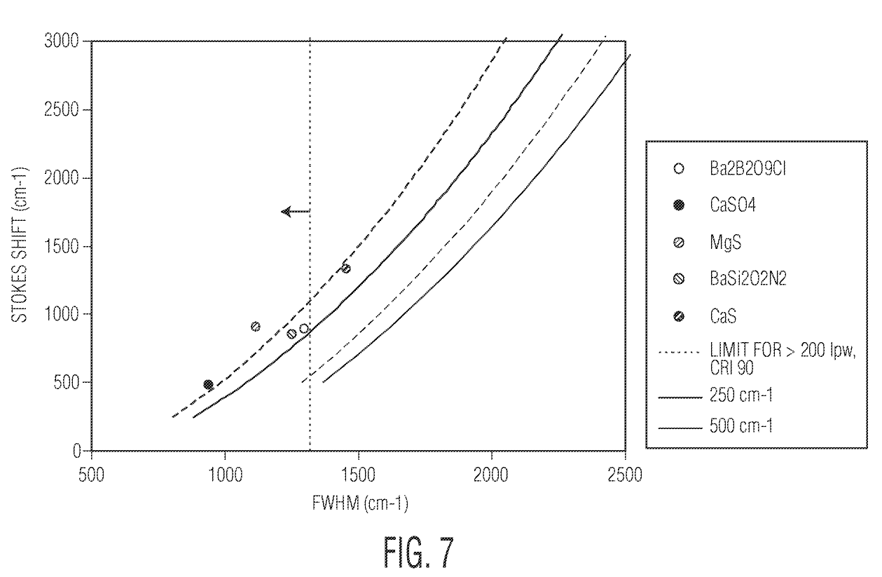

FIG. 7 depicts Stokes shift and spectral width (FWHM) data for Eu²⁺ in selected host lattices, with the upper limit of FWHM needed to reach a luminous efficacy of >200 lm/W white (CCT=2700 K, R_{a,8}=90, 75% efficiency blue pump LED) indicated by the vertical dotted line, which corresponds to an emission FWHM of ˜50 nm. The curves show calculated values for phonon frequencies of 250 and 500 cm⁻¹ for temperatures of 25° C. (dashed lines) and 100° C. (continuous lines). The calculations show that small Stokes shifts are correlated with low phonon energies.

Therefore, a FWHM of ˜50 nm (Γ˜1320 cm⁻¹ at 615 nm peak) is needed for a red emitter to reach 200 lm/W (2700 K, R_{a,8}=90, λₚᵤₘₚ=460 nm). As a lower limit for the Eu²⁺ emission width, a value of FWHM ˜37 nm can be approximated for a red emitter if the width of the most narrow known room temperature Eu²⁺ emission (CaSO₄:Eu; Γ=940 cm⁻¹) is used as a calculation basis.

A drawback with some typical small FWHM red phosphors is a lower quenching temperature, above which performance begins to significantly degrade, such as lowered intensity, peak emission shift, and broader bandwidth. This is also the case for quantum dots. Therefore, spacing the low FWHM (50 nm or less) phosphor from the blue LED to avoid the high temperature, as shown in FIG. 2, may be preferable to avoid exceeding the quenching temperature.

Additionally, although some Eu³⁺ type red phosphors have an extremely low FWHM down to less than 5 nm, such Eu³⁺ type red phosphors are unsuitable for use in generating a white light with a high CRI, since the R9 value is poor (R9 is a special CRI developed by the CIE relating to the color rendering of deep red colors). Such red phosphors are described in U.S. Pat. No. 6,252,254 to Soules et al., incorporated herein by reference.

Therefore, the FWHM of the red phosphor or quantum dots should be between about 30 nm-50 nm. However, a CRI above 90 can still be achieved under certain conditions with a red phosphor with FWHM of 5 nm or greater.

It is desirable that the red phosphor contain nitrogen, since nitrogen results in a rigid host lattice (causing a stable spectrum vs. temperature) and a high thermal quenching threshold, and a larger bandgap. Red phosphors that contain nitrogen, such as BSSNE, are particularly suitable because of low FWHM, good CRI, and reliable performance in high temperatures. The FWHM of BSSNE is slightly under 80 nm.

Another analysis of suitable red phosphors follows. Suitable red wavelength conversion materials include Eu(II) doped nitride phosphors with condensed host lattices of type A_{a-z}-B_{b}-C_{c}-Xₓ:Eu_{z}. “A” is a substitutable cation from the group of Sr, Ba, Ca, La, and Lu; “B” is a non-substitutable cation from the group of Li and Mg; “C” is a host lattice cation from the group of Si, Al, B, Ga, P, and Ge; “X” is an anion from the group of N, O, S, F, and Cl; and 0.5≦c/x≦0.75. Preferably, the divalent Eu activator ion is mainly coordinated by N atoms that are not bonded terminal but bridging with respect to more electropositive host lattice atoms of type C such as silicon, aluminum, gallium, magnesium, boron, phosphorus, or germanium. The degree of condensation may be expressed by the ratio of the host lattice cations to anions c/x and should fall within the range 0.5 to 0.75. For example, BSSNE has a value of Si/N=0.625. Such a condensed host structure is sufficiently stable against hydrolysis and delivers the required amount of covalent bonding towards the divalent Eu activator atoms that is needed to lower its net positive charge to a level required for absorption of blue LED light and emission in the orange-red spectral region.

The spectral width (FWHM) of emission was found to be correlated with the Stokes shift ΔS of the luminescence. A small Stokes shift typically leads to a narrow emission band. As proposed in the non-patent literature, P. Henderson, G. Imbusch (Eds.), Optical Spectroscopy of Inorganic Solids, Clarendon Press, Oxford, 1989, the bandwidth as function of the temperature can be approximated by

FWHM(T)=2.36 h/2πω(S)^{1/2}[cot h(h/2πω)2 kT)])^{1/2},

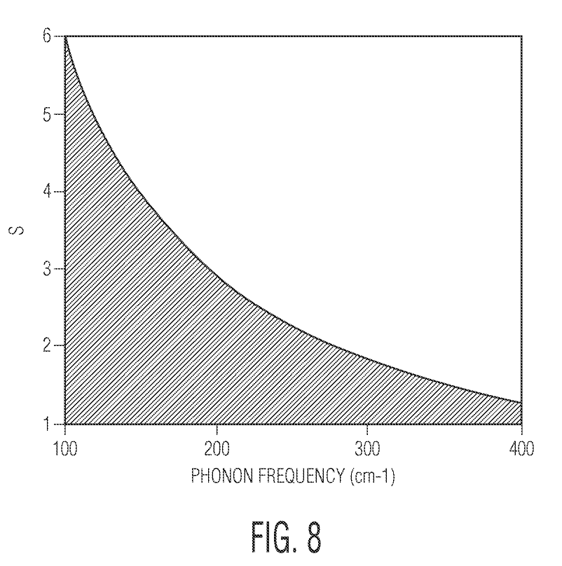

with S being the Huang-Rhys coupling parameter and h/2πω the mean phonon frequency. A suitable red phosphor would be one wherein the red emission is characterized by a Huang-Rhys coupling parameter S≦4 and a mean phonon frequency h/2πω≦300 cm⁻¹. A preferred red phosphor with a peak emission at 615 nm and FWHM ≦50 nm (˜1324 cm⁻¹ in wave numbers) thus is characterized by a low phonon frequency and/or a small Huang-Rhys coupling parameter S. At 100° C., which is a typical phosphor temperature in high power phosphor-converted LEDs, values for the mean phonon frequency and S are restricted to the area in the lower left of FIG. 8. FIG. 8 illustrates the phonon frequency and S values (to the left of the curve) that result in red emission with a peak at 615 nm and FWHM≦50 nm at T=100° C. Preferably, a suitable red emitting Eu(II) phosphor should show values for S≦4 and h/2πω≦300 cm⁻¹, more preferably S 2.5 and h/2πω≦200 cm⁻¹.

Preferably, the red emitting Eu(II) phosphor should also show coordination numbers of the Eu(II) activator between 6 and 8 and an activator—ligand arrangement that leads to a strong splitting of the Eu(II) 5d levels required for red emission in combination with a small Stokes shift. The activator—ligand contact length should lie in the range 210-320 pm. IN other words, a suitable red phosphor is characterized by a six fold to eightfold coordination of the red emitting activator by its ligands and activator—ligand contact lengths in the 210-320 pm range.

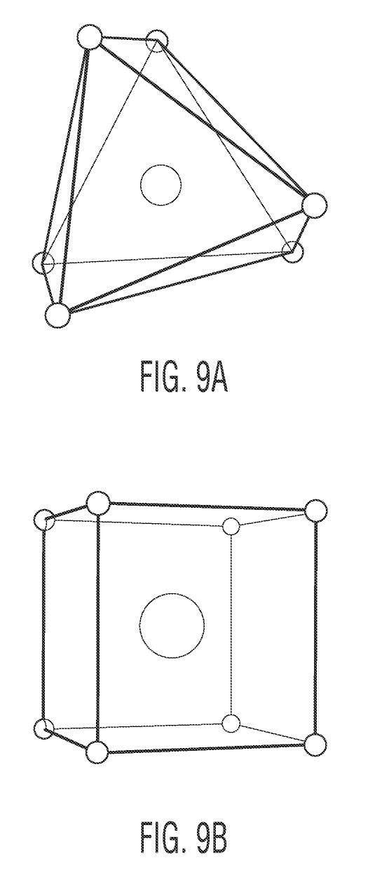

FIGS. 9A and 9B show suitable coordination polyhedra for activator sites in red emitting nitride phosphor systems that are suitable for the design of a narrow red emitting material. FIG. 9A shows a MN^{[2]}₆ polyhedron in a red phosphor of BaM^{I}_{3-x-z}M^{II}ₓSi₆₋ₐAlₐO₁₋ₓ₊ₐN₁₀₊ₓ₋ₐ:Eu_{z} with M^{I}=Ba, Ca, Sr, Mg; M^{II}=La, Gd, Lu, Y, Sc, Ce, Pr, Sm; 0≦x≦1, 0≦z≦0.1, 0≦a≦3. FIG. 9B shows a MN^{[3]}₈ polyhedron in M₁₋ₓMg_{3-y}Ge_{1-y}Ga_{2y}N₄:Euₓ.

A suitable red emitting phosphor may be cubic BaM^{I}_{3-x-z}M^{II}ₓSi₆₋ₐ,AlₐO₁₋ₓ₊ₐN₁₀₊ₓ₋ₐ:Eu_{z} with M^{I}=Ba, Ca, Sr, Mg; M^{II}=La, Gd, Lu, Y, Sc, Ce, Pr, Sm; 0≦x≦1, 0≦z≦0.1, 0≦a≦3. The material system in general and its application as a white emitting phosphor based on Eu(II) and Ce(III) codoping is disclosed in WO2008096291A1, by Peter Schmidt et al., and assigned to Koninklijke Philips Electronics NV, incorporated herein by reference. Such a white emitting phosphor emits red, green, and blue, and is excited by a UV emitting LED. If the exciting LED emits blue light, the CeIII doping for blue emission is not necessary.

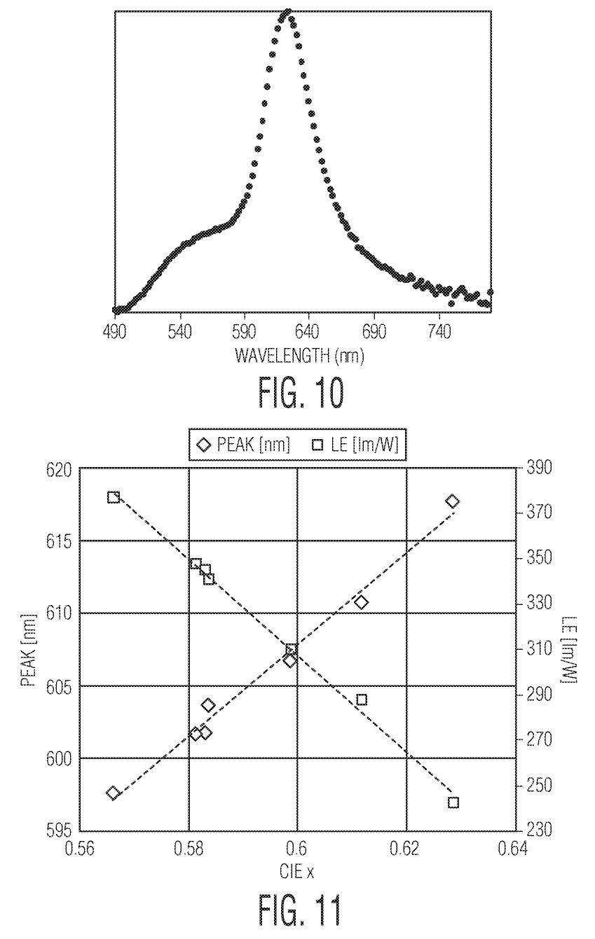

A composition suitable to form a narrow red emitting phosphor under blue light excitation is, for example, Ba₂Ca₂Si₆ON₁₀:Eu(1%), whose emission spectra is shown in FIG. 10. FIG. 10 illustrates the emission spectrum (446 nm excitation) of Ba₂Ca₂Si₆ON₁₀:Eu(1%), showing red peak emission at 622 nm and FWHM=50 nm. By changing the Ba/Ca ratio and the Eu concentration of the red phosphor, the peak position may be further adjusted. A larger value for Ba/Ca leads to a shift of the red emission to higher energies while a smaller value leads to a shift to smaller energies. The additional green emission component may be used for white light generation or reabsorbed by the small Stokes shift red emitting centers, preferably if the red emitting phosphor is applied as a dense sintered ceramic.

A less preferred FWHM of 75 nm can be achieved with a (Ba_{1-x-y-z}SrₓCa_{y})₂Si₅₋ₐAlₐOₐN₈₋ₐ:Eu_{z} (“BCSSNE”) red phosphor with 0<x≦0.75; 0<y≦0.1; 0.002≦z≦0.025; 0<a≦1.5 wherein the Ba:Sr:Ca ratio and Eu doping level is selected to maximize spectral lumen equivalent while maintaining a minimum CRI at the color temperature of interest.

The graph of FIG. 11 shows peak maxima, CIE×color coordinates and lumen equivalent values that can be obtained with different BCSSNE ceramics. A red shift of the Eu(II) emission is obtained by decreasing the Ba concentration and/or increasing the Eu concentration. A preferred composition is e.g., (B_{0.45} Sr_{0.5}Ca_{0.04})₂Si_{4.98}Al_{0.02}O_{0.02}N_{7.98}:EU_{0.02} with a concentration of ceramic grains of at least 90 vol % (preferably >95%) in a ceramic matrix with at least 98% (preferably >99%) relative density. Ceramic grains of other phases like (Ba,Sr)Si₇N₁₀ and (Ba,Sr, Ca)₂SiO₄ should show concentrations of less than 10 vol % (preferably <5%).

Preferably, the ceramic BCSSNE grains show a core-shell type structure with ([Sr]+[Ca])ₛₕₑₗₗ/([Sr]+[Ca])_{core}<1 and an average grain size>2 μm. We discovered that “seeding” of BCSSNE ceramics (or also powders) with more Sr and/or Ca rich seed grains leads to an improved micro structure with coarser grains and thus less light scattering.

The light from the blue LED die combines with the light from the red conversion material and a green conversion material to produce white light having the characteristics described above.

Green Phosphors

A suitable green phosphor can have a much higher FWHM because the entire bandwidth of green is visible to the human eye. Generally, to achieve a high spectral lumen equivalent of >300 lm/W, a correlated color temperature (CCT) of 2700K, and a CRI of >90, the FWHM of the green phosphor needs to be greater than about 60 nm and the FWHM of the red phosphor needs to be less than 50 nm. This assumes that the pump is a blue LED emitting a peak wavelength between 430-480 nm. The difference between a peak wavelength of the blue light emitted by the LED and the peak wavelength of the green down-converter material should be less than 100 nm. The peak wavelength of the green down-converter material should fall within the range of 530-580 nm.

Suitable green phosphors may be members of the Ce(III) activated garnet family such as Lu_{3-x-y}M^{I}ₓAl_{5-z}M^{II}_{z}O₁₂:Ce_{y} (M^{I}=Y, Gd, Pr, Sm, Ho, Yb, La; M^{II}=Ga, Sc), including for example Lu₃Al₅O₁₂:Ce (LuAG); or Ca_{3-x-y}M^{I}ₓSc_{2-z}M^{II}_{z}Si₃₋ᵤM^{III}ᵤO₁₂:Ce_{y} (M^{I}=Y, Gd, Pr, Sm, Ho, Yb, La; M^{II}=Ga, Lu, Mg, Al; M^{III}=Ge, Al), including for example Ca₃Sc₂Si₃O₁₂:Ce. Alternatively, Eu(II) activated SiON phosphors of composition Sr_{1-x-y}MₓSi₂O₂N₄:Eu_{y} (M=Ca, Ba) or Ba_{3-x-y-z}MₓLa_{z}Si_{6-z}Al_{z}O₁₂N₂:EU_{y} (M=Ca, Ba) may be used. Other suitable green phosphors are orthosilicates Ba₂₋ₓMₓSiO₄:Eu (M=Sr, Ca), including BaSrSiO₄:Eu, and thiogallates such as Sr_{1-x-y}MₓGa₂S₄:Eu_{y} (M=Ba, Ca), including for example SrGa₂S₄:Eu.

Efficient Eu²⁺ doped green emitting nitride compounds are known for the layered SiON materials class with M/Si=½ stoichiometry (M=Sr, Ba). Because of the narrower emission spectra compared to Ce³⁺ doped systems, green emitting SiONes are suitable phosphors for application in higher CCT white LEDs, because there the spectral width of the green emission significantly influences maximum R_{a,8} and lumen equivalent. Examples of SiON materials already tested in ceramic form are SrSi₂O₂N₂:Eu (“SSONE”, λₑₘ=538 nm, FWHM=72 nm) and Ba₃Si₆O₁₂N₂:Eu (a material published by Mitsubishi Chemical, λₑₘ˜525 nm, FWHM=62 nm). Both materials can show high ηₚₕ (>90%), excellent thermal quenching properties and high chemical stability. The manufacturability of polycrystalline ceramic converters of the latter material can be greatly enhanced by a lanthanum and aluminum containing transient glass phase that devitrifies during cooling of the sintered ceramic. Suitable compositions of such a preferred material are given by Ba_{3-x-y}LaₓSi₆₋ₓAlₓO₁₂N₂:Eu_{y} (0.003≦x≦0.02). Especially remarkable for fundamental reasons is BaSi₂O₂N₂:Eu (“BSONE”, λₑₘ˜500 nm, FWHM=33 nm), a material that fulfils all structural requirements for narrow Eu²⁺ emission listed above except for the N^{[2]} coordination that would be needed for red emission.

It should be noted that the cited green emitting SiON materials from above (and Ce³⁺ doped garnets discussed above) show limitations with respect to the maximum blue excitation wavelength given by the materials' Stokes shifts. Efficient absorption is only possible up to ˜460 nm if the activator concentrations are optimized. Especially Lumiramic™ technology has its advantages here, since the required optical thickness for efficient absorption can be more easily realized compared to powder phosphor solutions because of the higher activator concentrations needed in the latter approach (or significantly larger grain sizes). Longer wavelength blue excitation will require smaller Stokes shift green emitters with, e.g., the absorption and emission properties of BaSi₂O₂N₂:Eu but red-shifted by ˜20-50 nm.

The possible phosphor materials have—in the case of proximity to the pump LED shown in FIG. 1—to meet stringent criteria with respect to temperature dependence and/or temperature dependent photo-saturation. This excludes, e.g., CaS:Eu and SrS:Eu, which from their FWHM of the emission line would otherwise appear rather attractive. A good red phosphor that can withstand high temperatures when deposited over the surface of a high power blue LED is (Ba,Sr, Ca)₂Si₅₋ₐAlₐOₐN₈₋ₐ:Eu²⁺ (BCSSNE).

Semiconductor Nano Particles

Semiconductor nanoparticles, or “quantum dots” (QDs), have been considered for a long time as an efficient means for converting blue or near-UV LED light into any visible or near-IR wavelength. Very narrow FWHM down to ˜30 nm or even lower can be expected. The obvious advantage of tunability of the emission by size control of the dots, however, goes hand-in-hand with a very small Stokes' shift, which gives rise to (multiple) re-absorption/emission processes, with (1−η_{QD}) getting lost in each of them. Here, η_{QD} designates the quantum efficiency of the conversion in a single process, approximated by a highly diluted system, e.g. QDs in liquid suspension.

Improvements to quantum efficiency of QDs incorporated into binders have been made over the last few years. Claims of η_{QD}˜90% are now made with respect to dilute solutions, and densification to layers as thin as ˜100 μm appears feasible. Also, scattering has been measured by passing a laser beam through QDs incorporated into an epoxy slab; it was estimated to be less than 2% outside an 8 degree cone. Based on these achievements, QD are practical for use in LEDs. One opportunity is the red enhancement of warm white LEDs to increase luminous efficacy without sacrificing color rendering properties too much. Peak emission wavelength and FWHM would need to be tuned for maximum efficacy while maintaining minimum required color rendering properties. Another opportunity is filling in of the “cyan gap” that can be present in blue-pumped down-conversion LEDs for which the green phosphor Stokes shift is on the large side.

CdSe and InP based quantum dots are the most suitable red converters. In principle, every semiconductor with a bandgap larger than 1.8 eV, and which can be made into stable nanoparticles, is suitable for this purpose, as the specific size of the particles determines the emission wavelength. A preferred peak wavelength of 620 nm is achieved with a particle size distribution (PSD) of 4.7 to 5.2 nm. The specifics of tuning wavelength and FWHM depend, however, not only on the PSD but also on the embedding material and the concentration of quantum dots. The level of expertise by quantum dot manufacturers is such that suitable quantum dot material can be produced for used with a blue LED without undue experimentation once performance specifications are provided.

Suitable green emitting quantum dots are based preferentially on CdS but have to have smaller particle sizes than red emitting ones. Sizes around 2.5 nm will give peak wavelengths around 530 nm. A relatively broad particle size distribution (PSD) from 2 to 2.6 nm can yield a reasonably wide emission, such as including 50 nm FWHM. As for the desired high Ra, the green emission should not be too narrow. Producing larger than 50 nm FWHM quantum dot emissions has not yet been a goal.

Using two down-converting phosphors (green and red), the green of which has relatively large Stokes' shift, Ra is not only determined by the red phosphors long wavelength emission, but also by the cyan gap or dip in the final spectrum, caused by this finite Stokes' shift. This limitation can be overcome and Ra significantly improved by adding QDs into a binder layer or into the resin containing the powder phosphor(s). The QD material again would be CdSe or InP.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A light emitting device comprising:
a light emitting diode (LED) die that emits visible blue light in a wavelength range of about 450-470 nm;
a first wavelength conversion material in a light path of the LED die, the first wavelength conversion material being energized by the blue light and wavelength converting the blue light to emit a visible red light having a peak wavelength between about 605-625 nm with a full-width-half-maximum (FWHM) between 5 nm and 80 nm; and
a second wavelength conversion material in the light path of the LED die, the second wavelength conversion material being energized by the blue light and wavelength converting the blue light to emit a visible green light having a FWHM greater than 40 nm, wherein the combination of the blue light, red light, and green light produces a white light providing a color rendering of R_{a,8}>90 and a color temperature of between 2500K-5000K,
wherein the LED die outputs at least 100 W/cm² without saturation of the first wavelength conversion material, with a junction temperature over 100 degrees C.

2. The device of claim 1 wherein the FWHM of the first wavelength conversion material is less than 50 nm.

3. The device of claim 1 wherein the FWHM of the first wavelength conversion material is less than 30 nm.

4. The device of claim 1 wherein the first wavelength conversion material is a phosphor.

5. The device of claim 4 wherein the first wavelength conversion material produces Eu²⁺ red emission.

6. The device of claim 4 wherein a red emission of the first wavelength conversion material is characterized by a Huang-Rhys coupling parameter S≦4 and a mean phonon frequency h/2πω≦300 cm⁻¹.

7. The device of claim 4 wherein the first wavelength conversion material is characterized by a sixfold to eightfold coordination of a red emitting activator by its ligands and activator—ligand contact lengths in the 210-320 pm range.

8. The device of claim 4 wherein the first wavelength conversion material is a A_{a-z}-B_{b}-C_{c}-Xₓ:Eu_{z} compound with A=(Sr, Ba, Ca, La, Lu); B=(Li, Mg); C=(Si, Al, B, Ga, P, Ge); X=(N, O, S, F, Cl); and 0.5≦c/x≦0.75.

9. The device of claim 4 wherein the first wavelength conversion material is BaM^{I}_{3-x-z}M^{II}ₓSi₆₋ₐAlₐO₁₋ₓ₊ₐN₁₀₊ₓ₋ₐ:Eu_{z} with M^{I}=Ba, Ca, Sr, Mg; M^{II}=La, Gd, Lu, Y, Sc, Ce, Pr, Sm; 0≦x≦1, 0≦z≦0.1, 0≦a≦3.

10. The device of claim 1 wherein the first wavelength conversion material is a quantum dot material formed of semiconductor nanoparticles.

11. The device of claim 1 wherein the first wavelength conversion material is BCSSNE.

12. The device of claim 1 wherein the FWHM of the second conversion wavelength material is less than 95 nm.

13. The device of claim 1 wherein a difference between a peak wavelength of the blue light emitted by the LED die and a peak wavelength of the second wavelength conversion material is less than 100 nm.

14. The device of claim 1 wherein the second wavelength conversion material is a green phosphor.

15. The device of claim 1 wherein the second wavelength conversion material is a quantum dot material formed of semiconductor nanoparticles.

16. The device of claim 1 wherein at least the first wavelength conversion material is in direct thermal contact with the LED die.

17. The device of claim 1 wherein at least the first wavelength conversion material is remote from the LED die.

18. The device of claim 1 wherein both the first wavelength conversion material and the second wavelength conversion material are in thermal contact with the LED die, wherein the first wavelength conversion material and the second wavelength conversion material do not saturate and reliably operate at a temperature over 100 degrees C.
